(19) United States
(12) Patent Application Publication
(10) Pub. No.: US 2012/0037314 A1
(43) Pub. Date: Feb. 16, 2012

(54) SUBSTRATE PROCESSING APPARATUS AND SIDE WALL COMPONENT

(75) Inventors: Shosuke ENDOH, Nirasaki-shi (JP); Tsuyoshi MORIYA, Nirasaki-shi (JP); Akitaka SHIMIZU, Nirasaki-shi (JP)

(73) Assignee: TOKYO ELECTRON LIMITED, Tokyo (JP)

(21) Appl. No.: 13/278,765

(22) Filed: Oct. 21, 2011

Related U.S. Application Data
(62) Division of application No. 11/691,863, filed on Mar. 27, 2007.
(60) Provisional application No. 60/789,602, filed on Apr. 6, 2006.

(30) Foreign Application Priority Data
Mar. 28, 2006 (JP) 2006-089164

(51) Int. Cl. H01L 21/00; C23F 1/00

(52) U.S. Cl. 156/345.34

(57) ABSTRACT

A substrate processing apparatus that enables abnormal electrical discharges and metal contamination to be prevented from occurring. A processing chamber is configured to house and carry out predetermined plasma processing on a substrate. A lower electrode is disposed on a bottom portion of the processing chamber and has the substrate mounted thereon. An upper electrode is disposed in a ceiling portion of the processing chamber. A side wall component covering a side wall of the processing chamber faces onto a processing space between the upper electrode and the lower electrode. The side wall component has at least one electrode layer to which a DC voltage is applied. An insulating portion made of an insulating material is present at least between the electrode layer and the processing space and covers the electrode layer. The insulating portion is formed by thermally spraying the insulating material.

### CROSS-REFERENCE TO RELATED APPLICATIONS

This application is a divisional application of application Ser. No. 11/691,863 filed Mar. 27, 2007, the entire contents of which is incorporated herein by reference. Ser. No. 11/691,863 claims the benefit of priority under 35 U.S.C. §119(e) of U.S. Provisional Application No. 60/789,602 filed Apr. 6, 2006, and claims the benefit of priority under 35 U.S.C. §119 from Japanese Patent Application No. 2006-089164, filed Mar. 28, 2006.

### BACKGROUND OF THE INVENTION

1. Field of the Invention

The present invention relates to a substrate processing apparatus and a side wall component, and in particular relates to a substrate processing apparatus, and a side wall component of a processing chamber of the substrate processing apparatus.

2. Description of the Related Art

A substrate processing apparatus that carries out plasma processing on wafers as substrates has a processing chamber in which a wafer is housed, the wafer being subjected to the plasma processing by plasma produced in the processing chamber. The processing chamber, for example, has a cylindrical shape, and is made of a conductive material, for example aluminum.

The plasma in a processing chamber may be unevenly distributed due to various factors, and in this case it is difficult to maintain the uniformity of the plasma processing carried out on the wafers. It is thus necessary to control the distribution of the plasma. Moreover, particles float through the processing chamber, and if such particles become attached to the front surface of the wafer, then defects will arise in semiconductor devices manufactured from the wafer; it is thus necessary to remove particles from the vicinity of the wafer in the processing chamber.

The plasma and particles are charged, and hence in recent years methods of controlling the distribution of the plasma in the processing chamber and methods of controlling the behavior of particles by applying a predetermined DC voltage to a wall member of the processing chamber have been developed. In particular, as the latter, there is known a method in which the behavior of particles positively charged due to a sheath is controlled through the timing of application of a DC voltage to a wall member (see, for example, Japanese Laid-open Patent Publication (Kokai) No. 2005-072175). The wall member to which the DC voltage is applied is an aluminum member coated with alumite.

However, it is difficult to keep the film thickness of such alumite uniform, and hence thin film portions of the alumite arise locally on the wall member. Upon a DC voltage being applied to such a wall member, there is a problem of abnormal electrical discharges being produced from the thin film portions.

Moreover, alumite has low resistance, and hence if a DC voltage is repeatedly applied to the wall member, then the alumite may undergo dielectric breakdown, and hence portions where the aluminum is exposed may arise on the wall member. In this case, there is a problem of not only abnormal electrical discharges, but moreover metal contamination arising in the processing chamber.

### SUMMARY OF THE INVENTION

The present invention provides a substrate processing apparatus and a side wall component that enable abnormal electrical discharges and metal contamination to be prevented from occurring.

In a first aspect of the present invention, there is provided a substrate processing apparatus comprising a processing chamber configured to house and carry out predetermined plasma processing on a substrate, a lower electrode that is disposed on a bottom portion of the processing chamber and has the substrate mounted thereon, and an upper electrode that is disposed in a ceiling portion of the processing chamber, the substrate processing apparatus further comprising: a side wall component covering a side wall of the processing chamber that faces onto a processing space between the upper electrode and the lower electrode; wherein the side wall component has at least one electrode layer to which a DC voltage is applied, and an insulating portion made of an insulating material that is present at least between the electrode layer and the processing space and that covers the electrode layer, and the insulating portion is formed by thermally spraying the insulating material.

According to the above construction, portions where the insulating portion is thin do not arise in the side wall component, and hence abnormal electrical discharges can be prevented from occurring. Moreover, the thermally sprayed film is highly resistant, and hence portions where the electrode layer is exposed do not arise, and thus metal contamination can be prevented from occurring.

The side wall component can be disposed such as to not face a front surface of the substrate mounted on the lower electrode.

According to the above construction, particles behaving in accordance with the DC voltage applied to the electrode layer of the side wall component do not move toward the front surface of the substrate, and hence particles can be prevented from becoming attached to the front surface of the substrate.

The substrate processing apparatus can further comprise an exhaust portion configured to exhaust gas out from the processing chamber, the electrode layer can comprises at least a first electrode and a second electrode, the second electrode can be disposed between the first electrode and the exhaust portion, and an absolute value of a DC voltage applied to the second electrode can be greater than an absolute value of a DC voltage applied to the first electrode.

According to the above construction, charged particles are accelerated from the first electrode toward the second electrode, and thus led into the exhaust portion. As a result, particles can be removed from the processing chamber effectively.

The substrate processing apparatus can further comprise an exhaust portion configured to exhaust gas out from the processing chamber, and a thickness of the insulating portion can decrease from the processing space toward the exhaust portion.

According to the above construction, the absolute value of a potential at the surface of the insulating portion increases from the processing space toward the exhaust portion. Charged particles are thus led into the exhaust portion while being accelerated. As a result, particles can be removed from the processing chamber effectively.

The electrode layer can have at least a first terminal and a second terminal, and a predetermined difference can be set between a voltage applied to the first terminal and a voltage applied to the second terminal.

According to the above construction, a current flow through the electrode layer so that heat is released. Particles attached to a member can be removed through thermal stress produced upon heating the member. As a result, by making the electrode layer release heat, particles attached to the side wall component can be removed efficiently through thermal stress.

The substrate processing apparatus can further comprise a gas introducing apparatus configured to introduce a predetermined gas into the processing chamber, and a fluctuating DC voltage can be applied to each of the at least one electrode layer while the gas introducing apparatus is introducing the predetermined gas into the processing chamber.

According to the above construction, a fluctuating DC voltage is applied to the electrode layer while the predetermined gas is being introduced into the processing chamber. Particles attached to a member can be removed through electromagnetic stress produced by applying a fluctuating voltage to the member. As a result, by applying the fluctuating DC voltage to the electrode layer, particles attached to the side wall component can be removed efficiently through electromagnetic stress. Moreover, the removed particles are exhausted out of the processing chamber efficiently by viscous flow produced by the predetermined gas.

The electrode layer can be formed through thermal spraying of a conductive material.

According to the above construction, an electrode layer having a desired shape can easily be realized, and hence a desired potential distribution can easily be realized over the side wall component. As a result, ideal plasma distribution control and ideal particle behavior in the processing chamber can be realized.

Moreover, in a second aspect of the present invention, there is provided a side wall component in a substrate processing apparatus comprising a processing chamber configured to house and carry out predetermined plasma processing on a substrate, a lower electrode that is disposed on a bottom portion of the processing chamber and has the substrate mounted thereon, and an upper electrode that is disposed in a ceiling portion of the processing chamber, the side wall component covering a side wall of the processing chamber such as to face onto a processing space between the upper electrode and the lower electrode; wherein the side wall component has at least one electrode layer to which a DC voltage is applied, and an insulating portion made of an insulating material that is present at least between the electrode layer and the processing space and that covers the electrode layer; and the insulating portion is formed by thermally spraying the insulating material.

The above and other objects, features and advantages of the invention will become apparent from the following detailed description taken in conjunction with the accompanying drawings.

### BRIEF DESCRIPTION OF THE DRAWINGS

FIG. 1 is a sectional view schematically showing the construction of a substrate processing apparatus according to a first embodiment of the present invention;

FIG. 2 is a view which is useful in explaining a particle removal method for the substrate processing apparatus according to the above embodiment;

FIGS. 3A and 3B are sequence diagrams showing the timing of application of a DC voltage to an upper electrode layer and a lower electrode layer of a deposit shield appearing in FIG. 1, FIG. 3A showing an example of the timing of the DC voltage application, and FIG. 3B showing another example of the timing of the DC voltage application;

FIG. 4 is a sequence diagram which is useful in explaining a deposit removal method carried out in the substrate processing apparatus shown in FIG. 1; and

FIG. 5 is a sectional view schematically showing the construction of a substrate processing apparatus according to a second embodiment of the present invention.

### DESCRIPTION OF THE PREFERRED EMBODIMENT

The present invention will now be described in detail below with reference to the accompanying drawings showing an embodiment thereof.

First, a substrate processing apparatus according to a first embodiment of the present invention will be described.

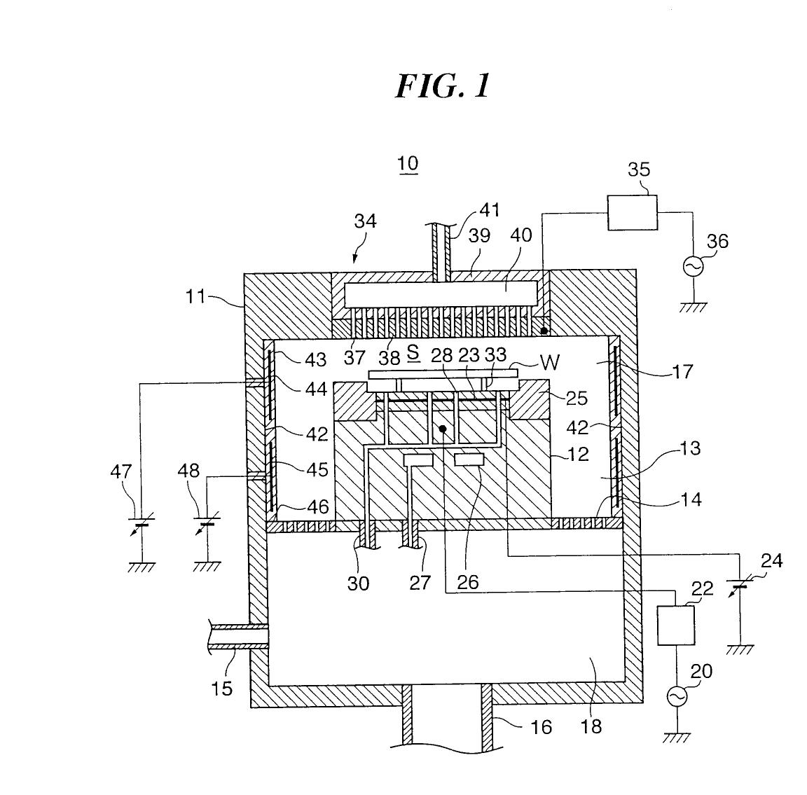

FIG. 1 is a sectional view schematically showing the construction of the substrate processing apparatus according to the present embodiment. The substrate processing apparatus is constructed such as to carry out etching processing on semiconductor wafers as substrates.

As shown in FIG. 1, the substrate processing apparatus 10 has a cylindrical chamber 11 (processing chamber) in which is housed a semiconductor wafer (hereinafter referred to merely as a the “wafer”) W having a diameter of, for example, 300 mm. A cylindrical susceptor 12 is disposed in the chamber 11 as a stage on which the wafer W is mounted.

In the substrate processing apparatus 10, a side exhaust path 13 that acts as a flow path through which gas above the susceptor 12 is exhausted out of the chamber 11 is formed between an inner wall of the chamber 11 and a side face of the susceptor 12. A baffle plate 14 is disposed part way along the side exhaust path 13.

The baffle plate 14 is a plate-shaped member having a large number of holes therein, and acts as a partitioning plate that partitions the chamber 11 into an upper portion and a lower portion. Plasma, described below, is produced in the upper portion (hereinafter referred to as the “reaction chamber”) 17 of the chamber 11 partitioned by the baffle plate 14. The susceptor 12 is disposed on a bottom portion of the reaction chamber 17. Moreover, a roughing exhaust pipe 15 and a main exhaust pipe 16 that exhaust gas out from the chamber 11 are provided opening out from the lower portion (hereinafter referred to as the “manifold”) 18 (exhaust portion) of the chamber 11. The roughing exhaust pipe 15 has a DP (dry pump) (not shown) connected thereto, and the main exhaust pipe 16 has a TMP (Turbo-Molecular Pump) (not shown) connected thereto. Moreover, the baffle plate 14 captures or reflects ions and radicals produced in a processing space S, described below, in the reaction chamber 17, thus preventing leakage of the ions and radicals into the manifold 18.

The roughing exhaust pipe 15 and the main exhaust pipe 16 exhaust gas in the reaction chamber 17 out of the chamber 11 via the manifold 18. Specifically, the roughing exhaust pipe 15 reduces the pressure in the chamber 11 from atmospheric pressure down to a low vacuum state, and the main exhaust pipe 16 is operated in collaboration with the roughing exhaust pipe 15 to reduce the pressure in the chamber 11 from atmospheric pressure down to a high vacuum state (e.g. a pressure of not more than 133 Pa (1 Torr)), which is at a lower pressure than the low vacuum state.

A lower radio frequency power source 20 is connected to the susceptor 12 via a matcher 22. The lower radio frequency power source 20 applies predetermined radio frequency electrical power to the susceptor 12. The susceptor 12 thus acts as a lower electrode. The matcher 22 reduces reflection of the radio frequency electrical power from the susceptor 12 so as to maximize the efficiency of the supply of the radio frequency electrical power into the susceptor 12.

A disk-shaped ESC electrode plate 23 comprised of an electrically conductive film is provided in an upper portion of the susceptor 12. A DC power source 24 is electrically connected to the ESC electrode plate 23. A wafer W is attracted to and held on an upper surface of the susceptor 12 through a Johnsen-Rahbek force or a Coulomb force generated by a DC voltage applied to the ESC electrode plate 23 from the DC power source 24. Moreover, an annular focus ring 25 is provided on an upper portion of the susceptor 12 so as to surround the wafer W attracted to and held on the upper surface of the susceptor 12. The focus ring 25 is exposed to the processing space S, and focuses the plasma in the processing space S toward a front surface of the wafer W, thus improving the efficiency of the etching processing.

An annular coolant chamber 26 that extends, for example, in a circumferential direction of the susceptor 12 is provided inside the susceptor 12. A coolant, for example cooling water or a Galden fluid, at a predetermined temperature is circulated through the coolant chamber 26 via coolant piping 27 from a chiller unit (not shown). A processing temperature of the wafer W attracted to and held on the upper surface of the susceptor 12 is controlled through the temperature of the coolant.

A plurality of heat-transmitting gas supply holes 28 are provided in a portion of the upper surface of the susceptor 12 on which the wafer W is attracted and held (hereinafter referred to as the “attracting surface”). The heat-transmitting gas supply holes 28 are connected to a heat-transmitting gas supply unit (not shown) by a heat-transmitting gas supply line 30. The heat-transmitting gas supply unit supplies helium gas as a heat-transmitting gas via the heat-transmitting gas supply holes 28 into a gap between the attracting surface of the susceptor 12 and a rear surface of the wafer W. The helium gas supplied into the gap between the attracting surface of the susceptor 12 and the rear surface of the wafer W transmits heat from the wafer W to the susceptor 12.

A plurality of pusher pins 33 are provided in the attracting surface of the susceptor 12 as lifting pins that can be made to project out from the upper surface of the susceptor 12. The pusher pins 33 are connected to a motor (not shown) by a ball screw (not shown), and can be made to project out from the attracting surface of the susceptor 12 through rotational motion of the motor, which is converted into linear motion by the ball screw. The pusher pins 33 are housed inside the susceptor 12 when a wafer W is being attracted to and held on the attracting surface of the susceptor 12 so that the wafer W can be subjected to the etching processing, and are made to project out from the upper surface of the susceptor 12 so as to lift the wafer W up away from the susceptor 12 when the wafer W is to be transferred out from the chamber 11 after having been subjected to the etching processing.

A gas introducing shower head 34 (gas introducing apparatus) is disposed in a ceiling portion of the chamber 11 (the reaction chamber 17) facing the susceptor 12. An upper radio frequency power source 36 is connected to the gas introducing shower head 34 via a matcher 35. The upper radio frequency power source 36 supplies predetermined radio frequency electrical power to the gas introducing shower head 34. The gas introducing shower head 34 thus acts as an upper electrode. The matcher 35 has a similar function to the matcher 22, described earlier.

The gas introducing shower head 34 has a ceiling electrode plate 38 having a large number of gas holes 37 therein, and an electrode support 39 on which the ceiling electrode plate 38 is detachably supported. A buffer chamber 40 is provided inside the electrode support 39. A processing gas introducing pipe 41 is connected to the buffer chamber 40. A processing gas supplied from the processing gas introducing pipe 41 into the buffer chamber 40 is supplied by the gas introducing shower head 34 into the chamber 11 (the reaction chamber 17) via the gas holes 37.

A deposit shield 43 is disposed as a side wall component on a side wall 42 of the chamber 11 such as to cover the side wall 42 and face onto the processing space S between the susceptor 12 and the gas introducing shower head 34. The deposit shield 43 has an upper electrode layer 44 (first electrode), a lower electrode layer 45 (second electrode), and an insulating portion 46 made of an insulating material, for example yttria (Y₂O₃), formed such as to enclose the upper electrode layer 44 and the lower electrode layer 45.

The deposit shield 43 is a cylindrical component, and is disposed such as to surround the susceptor 12. Moreover, the upper electrode layer 44 and the lower electrode layer 45 are each cylindrical, and are disposed one above the other in a vertical direction of the chamber 11 (a vertical direction in FIG. 1). Specifically, the upper electrode layer 44 is disposed such as to face onto the processing space S, and the lower electrode layer 45 is disposed between the upper electrode layer 44 and the manifold 18. Neither the upper electrode layer 44 nor the lower electrode layer 45 thus faces the front surface of the wafer W mounted on the susceptor 12.

Moreover, in the deposit shield 43, the insulating portion 46 is present between the upper electrode layer 44 and the processing space S, and furthermore between the lower electrode layer 45 and the side exhaust path 13. Consequently, neither the upper electrode layer 44 nor the lower electrode layer 45 is exposed to the reaction chamber 17.

The deposit shield 43 is manufactured by thermally spraying yttria onto the side wall 42 of the chamber 11 so as to form an insulating foundation layer, thermally spraying a conductive material that adheres well to ceramics, for example tungsten, nichrome or niobium, onto the foundation layer so as to form the lower electrode layer 45 and the upper electrode layer 44, and then thermally spraying yttria onto the lower electrode layer 45 and the upper electrode layer 44 so as to form a coating film. Here, the yttria foundation layer and coating film constitute the insulating portion 46. For a film formed by thermal spraying, there is little variation in film thickness, and hence portions where the insulating portion 46 is thin do not arise in the deposit shield 43. Moreover, a relatively high film thickness can easily be realized through thermal spraying, and hence the resistance of the insulating portion 46 can be increased. Furthermore, because the upper electrode layer 44 and the lower electrode layer 45 are also formed by thermal spraying, electrode layers having a desired shape can easily be realized by using masking tape or the like.

An upper DC power source 47 and a lower DC power source 48 are electrically connected to the upper electrode layer 44 and the lower electrode layer 45 respectively. A voltage applied to the lower electrode layer 45 can thus be controlled independently of a voltage applied to the upper electrode layer 44.

Radio frequency electrical power is supplied to the susceptor 12 and the gas introducing shower head 34 in the chamber 11 of the substrate processing apparatus 10 as described above so as to apply radio frequency electrical power into the processing space S, whereupon the processing gas supplied into the processing space S from the gas introducing shower head 34 is turned into high-density plasma, whereby ions and radicals are produced; the wafer W is subjected to the etching processing by the ions and so on.

Operation of the component elements of the substrate processing apparatus 10 described above is controlled in accordance with a program for the etching processing by a CPU of a controller (not shown) of the substrate processing apparatus 10.

In the substrate processing apparatus 10, when a wafer W is subjected to the etching processing, the ions and so on react with matter present on the front surface of the wafer so that a reaction product is produced. The reaction product becomes attached to the inner wall of the reaction chamber 17, and then the attached reaction product is detached during subsequent etching processing or the like, thus forming particles. The particles float through the reaction chamber 17, in particular the processing space S, and thus become attached to the front surface of a wafer W. Such attached particles cause defects in semiconductor devices manufactured from the wafer W, and hence the floating particles must be removed from the processing space S. For the substrate processing apparatus 10, particles are removed from the processing space S using a particle removal method as described below.

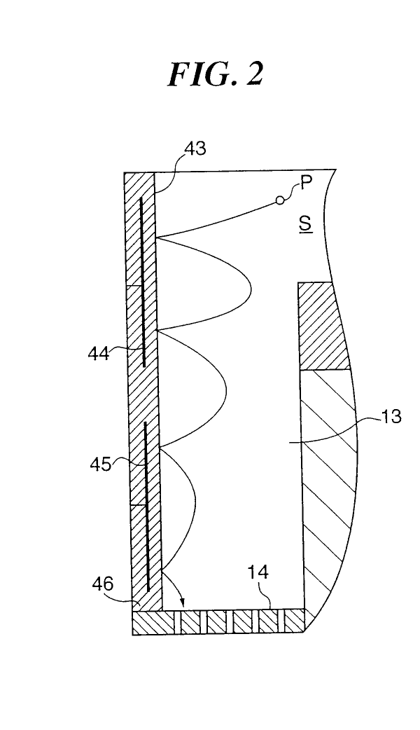

FIG. 2 is a view which is useful in explaining the particle removal method for the substrate processing apparatus according to the present embodiment.

As shown in FIG. 2, in the case that most of the particles P floating in the processing space S are negatively charged, a positive DC voltage is applied to each of the upper electrode layer 44 and the lower electrode layer 45. In this case, the value of the positive DC voltage applied to the lower electrode layer 45 is greater the value of the positive DC voltage applied to the upper electrode layer 44.

Here, the particles P floating through the processing space S are attracted to the deposit shield 43 by a Coulomb force due to the DC voltage applied to the upper electrode layer 44 (hereinafter referred to as the “Coulomb force from the upper electrode layer 44”) and thus undergo elastic collision with the deposit shield 43, and furthermore rebound toward the processing space S (or the susceptor 12). However, the Coulomb force from the upper electrode layer 44 continues to act on particles P that have rebounded, and hence these particles P are again attracted toward the deposit shield 43. The particles P thus repeatedly undergo elastic collision with the deposit shield 43. At this time, because the value of the positive DC voltage applied to the lower electrode layer 45 is greater the value of the positive DC voltage applied to the upper electrode layer 44, the Coulomb force due to the DC voltage applied to the lower electrode layer 45 (hereinafter referred to as the “Coulomb force from the lower electrode layer 45”) is greater the Coulomb force from the upper electrode layer 44. As a result, the charged particles P move through the side exhaust path 13 while being accelerated from in the vicinity of the upper electrode layer 44 toward in the vicinity of the lower electrode layer 45. Gas flow, for example viscous flow, arises in the side exhaust path 13 from the reaction chamber 17 toward the manifold 18, and hence particles P that have moved into the vicinity of the lower electrode layer 45 are led through the holes in the baffle plate 14 and into the manifold 18. Having been led into the manifold 18, the particles P are exhausted out of the chamber 11 by the roughing exhaust pipe 15 and the main exhaust pipe 16.

Note that in the case that most of the particles P floating in the processing space S are positively charged, it is preferable to apply a negative DC voltage to each of the upper electrode layer 44 and the lower electrode layer 45. In this case, the value of the negative DC voltage applied to the lower electrode layer 45 is preferably set to be more negative the value of the negative DC voltage applied to the upper electrode layer 44.

With the substrate processing apparatus described in Japanese Laid-open Patent Publication (Kokai) No. 2005-072175, an electrode layer for controlling the behavior of particles is also provided on a surface of the gas introducing shower head facing the wafer. Here, in the case, for example, that only negatively charged particles are present in the processing space, the particles can be attracted to the gas introducing shower head and thus kept away from the front surface of the wafer by applying a positive DC voltage to the electrode layer on the surface of the gas introducing shower head. However, in the case that not only negatively charged particles but also positively charged particles are present in the processing space, upon applying the positive DC voltage to the electrode layer on the surface of the gas introducing shower head, the positively charged particles are caused to move toward the front surface of the wafer. As a result, particles cannot be prevented from becoming attached to the front surface of the wafer.

In view of this, in the substrate processing apparatus 10, neither the upper electrode layer 44 nor the lower electrode layer 45 faces the front surface of the wafer W mounted on the susceptor 12. Consequently, in the case, for example, that a positive DC voltage is applied to each of the upper electrode layer 44 and the lower electrode layer 45, positively charged particles move only toward the processing space S or the susceptor 12, and do not move toward the front surface of the wafer W mounted on the susceptor 12. As a result, the particles can be prevented from becoming attached to the front surface of the wafer W.

Moreover, for the deposit shield 43, because the upper electrode layer 44 is disposed such as to face onto the processing space S, by changing the value of the DC voltage applied to the upper electrode layer 44, a potential difference between a potential at the surface of the deposit shield 43 and the processing space S (hereinafter referred to as the “deposit shield-processing space potential difference”) can be controlled. However, the method of controlling the deposit shield-processing space potential difference is not limited to this.

For example, the potential at the surface of the deposit shield 43 changes in accordance with the capacitance of the insulating portion 46 present between the upper electrode layer 44 and the processing space S (hereinafter referred to as the “coating film insulating portion”). The deposit shield-processing space potential difference can thus be controlled by changing the capacitance of the coating film insulating portion. Specifically, the deposit shield-processing space potential difference can be increased by reducing the thickness of the coating film insulating portion. The deposit shield-processing space potential difference affects the distribution of the plasma and the behavior of particles in the processing space S. As a result, by changing the capacitance of the coating film insulating portion, the distribution of the plasma and the behavior of particles in the processing space S can be controlled.

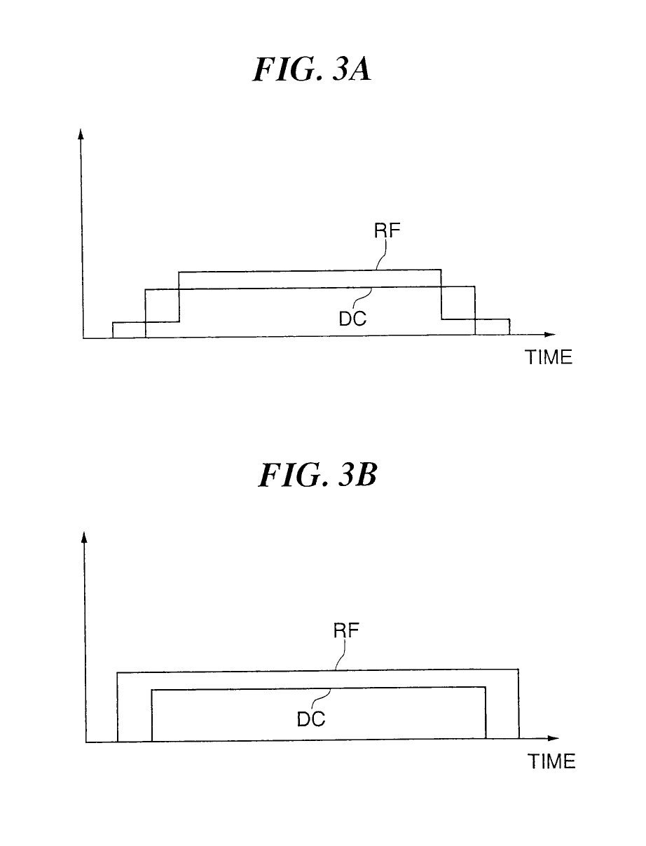

FIG. 3 are sequence diagrams showing the timing of application of a DC voltage to the upper electrode layer and the lower electrode layer of the deposit shield appearing in FIG. 1, FIG. 3A showing an example of the timing of the DC voltage application, and FIG. 3B showing another example of the timing of the DC voltage application.

In FIG. 3A, first, relatively low radio frequency electrical power (“RF” in FIG. 3A) is applied into the processing space S by the lower radio frequency power source 20 and the upper radio frequency power source 36. After that, the upper DC power source 47 and the lower DC power source 48 apply a DC voltage (“DC” in FIG. 3A) to the upper electrode layer 44 and the lower electrode layer 45 respectively. At this time, plasma is produced in the processing space S due to the application of the radio frequency electrical power, but particles floating through the plasma are attracted toward the deposit shield 43.

Next, relatively high radio frequency electrical power is applied into the processing space S, whereby high-density plasma is produced in the processing space S. As a result, the wafer W is subjected to the etching processing. Here, while the wafer W is being subjected to the etching processing, the application of the DC voltage to the upper electrode layer 44 and the lower electrode layer 45 is continued. Particles are thus attracted toward the deposit shield 43 while the wafer W is being subjected to the etching processing.

Next, after a predetermined time period has elapsed, relatively low radio frequency electrical power is applied into the processing space S, whereby the density of the plasma in the processing space S is reduced, and then the application of the DC voltage to the upper electrode layer 44 and the lower electrode layer 45 is stopped. The application of the radio frequency electrical power into the processing space S is then stopped.

Moreover, in FIG. 3B, relatively high radio frequency electrical power is applied into the processing space S by the lower radio frequency power source 20 and the upper radio frequency power source 36 from the outset. After that, the upper DC power source 47 and the lower DC power source 48 apply a DC voltage to the upper electrode layer 44 and the lower electrode layer 45 respectively. Moreover, while the wafer W is being subjected to the etching processing, the application of the DC voltage to the upper electrode layer 44 and the lower electrode layer 45 is continued. Particles are thus attracted toward the deposit shield 43 while the wafer W is being subjected to the etching processing.

Next, after a predetermined time period has elapsed, the application of the DC voltage to the upper electrode layer 44 and the lower electrode layer 45 is stopped. After that, the application of the radio frequency electrical power into the processing space S is stopped.

In the case of each of FIGS. 3A and 3B, particles floating through the plasma are attracted toward the deposit shield 43 when plasma is being produced in the processing space S. As a result, particles can be prevented from becoming attached to the front surface of the wafer W.

The sequence of the timing of the application of the DC voltage to the upper electrode layer 44 and the lower electrode layer 45 of the deposit shield 43 is not limited to being as described above, but rather may be any sequence in which the DC voltage application is started and stopped while radio frequency electrical power is being applied into the processing space S.

Reaction product as described earlier may become attached as deposit to the surface of the deposit shield 43. Moreover, because the deposit shield 43 attracts particles thereto, particles may become attached to the surface of the deposit shield 43.

In view of this, in the substrate processing apparatus 10, such deposit and so on is removed from the surface of the deposit shield 43 using a deposit removal method as described below.

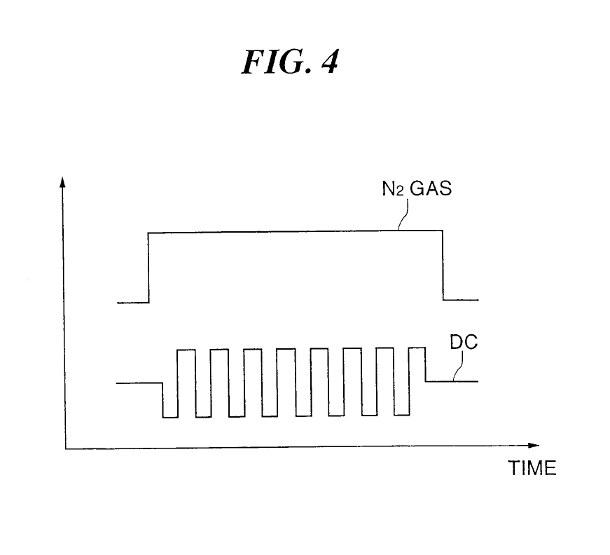

FIG. 4 is a sequence diagram which is useful in explaining the deposit removal method carried out in the substrate processing apparatus shown in FIG. 1.

In the deposit removal method, as shown in FIG. 4, first, N₂ gas (a predetermined gas) is introduced into the reaction chamber 17 at a predetermined flow rate from the gas introducing shower head 34. At this time, viscous flow from the reaction chamber 17 toward the manifold 18 is produced due to the N₂ gas.

Next, while continuing the introduction of the N₂ gas into the reaction chamber 17, the upper DC power source 47 and the lower DC power source 48 apply a DC voltage (“DC” in FIG. 4) that fluctuates between positive and negative to the upper electrode layer 44 and the lower electrode layer 45. At this time, deposit and so on attached to the surface of the deposit shield 43 is repeatedly subjected to electromagnetic stress due to the fluctuating DC voltage. As a result, the attachment of the deposit and so on is weakened, and hence some of the deposit is detached from the deposit shield 43. The deposit and so on whose attachment has been weakened is detached from the deposit shield 43 by the viscous flow, and the detached deposit and so on is led into the manifold 18 by the viscous flow, and is then further exhausted out of the chamber 11 by the roughing exhaust pipe 15 and the main exhaust pipe 16. As a result, deposit and particles on the surface of the deposit shield 43 in the substrate processing apparatus 10 can be removed efficiently.

The deposit removal method is not limited to being a method using a fluctuating DC voltage as described above, but rather may instead be a method using thermal stress as described below. Specifically, at least two terminals (not shown) are provided on each of the upper electrode layer 44 and the lower electrode layer 45, and a predetermined difference is set between a DC voltage applied to one of the terminals (the first terminal) and a DC voltage applied to another of the terminals (the second terminal). For example, a DC voltage of 10 V is applied to the first terminal, and a DC voltage of 5 V is applied to the other terminal. In this case, a current flows through each of the upper electrode layer 44 and the lower electrode layer 45 in accordance with the potential difference between the first terminal and the other terminal, and because each of the upper electrode layer 44 and the lower electrode layer 45 is made of tungsten or the like, each of the upper electrode layer 44 and the lower electrode layer 45 acts as a heater, releasing heat due to the current. As a result, the deposit shield 43 is heated. Upon the deposit shield 43 being heated, thermal stress acts on deposit due to a difference in thermal expansion between the deposit and the insulating portion 46, and hence the attachment of the deposit and so on is weakened. The deposit and so on whose attachment has been weakened is detached from the deposit shield 43 by the viscous flow and led into the manifold 18, and is then further exhausted out of the chamber 11. As a result, again, deposit and particles on the surface of the deposit shield 43 in the substrate processing apparatus 10 can be removed efficiently.

Moreover, to make each of the upper electrode layer 44 and the lower electrode layer 45 act as an electrode subjecting particles to a Coulomb force at the same time as acting as a heater, for example a DC voltage of 105 V may be applied to the first terminal, and a DC voltage of 100 V to the other terminal. As a result, as well as a current flowing through each of the upper electrode layer 44 and the lower electrode layer 45, the potential of each of the upper electrode layer 44 and the lower electrode layer 45 can be made to be approximately 100 V.

According to the substrate processing apparatus 10 described above, for the deposit shield 43, the insulating portion 46 is formed by thermally spraying yttria. As a result, portions where the insulating portion 46 is thin do not arise in the deposit shield 43, and hence abnormal electrical discharges can be prevented from occurring, and moreover workers getting an electric shock by touching such a thin film portion can be prevented. Moreover, the insulating portion 46 formed through the thermal spraying is highly resistant, and hence portions where the upper electrode layer 44 or the lower electrode layer 45 is exposed do not arise, and thus metal contamination can be prevented from occurring.

In the substrate processing apparatus 10, neither the upper electrode layer 44 nor the lower electrode layer 45 of the deposit shield 43 is disposed such as to face the front surface of a wafer W mounted on the susceptor 12. As a result, particles behaving in accordance with the DC voltage applied to the upper electrode layer 44 and the lower electrode layer 45 do not move toward the front surface of the wafer W, and hence particles can be prevented from becoming attached to the front surface of the wafer W.

Moreover, in the substrate processing apparatus 10, the at least one electrode layer of the deposit shield 43 is comprised of the upper electrode layer 44 and the lower electrode layer 45, and the absolute value of the DC voltage applied to the lower electrode layer 45, which is disposed between the upper electrode layer 44 and the manifold 18, is greater than the absolute value of the DC voltage applied to the upper electrode layer 44. Particles are thus accelerated from in the vicinity of the upper electrode layer 44 toward in the vicinity of the lower electrode layer 45 and hence led into the manifold 18. As a result, particles can be removed from the reaction chamber 17 effectively.

Furthermore, in the substrate processing apparatus 10, a predetermined difference may be set between a DC voltage applied to a first terminal of each of the upper electrode layer 44 and the lower electrode layer 45 and a DC voltage applied to another terminal of that upper electrode layer 44 or lower electrode layer 45. As a result, a current flows through the upper electrode layer 44 or lower electrode layer 45, and hence the upper electrode layer 44 or lower electrode layer 45 releases heat. Deposit and so on attached to the deposit shield 43 can thus be removed efficiently through thermal stress.

Moreover, to heat the side wall, it is generally necessary to provide a heater separately to the deposit shield 43, but for the substrate processing apparatus 10, the upper electrode layer 44 and so on of the deposit shield 43 acts as a heater. There is thus no need to provide a separate heater, and hence the construction of the substrate processing apparatus 10 can be simplified. Furthermore, in the substrate processing apparatus 10, the upper electrode layer 44 and the lower electrode layer 45, which are close to the surface of the deposit shield 43, each act as a heater. As a result, deposit and so on attached to the surface of the deposit shield 43 can be heated rapidly, and moreover the amount of heat required for the heating can be reduced.

Moreover, in the substrate processing apparatus 10, a DC voltage that fluctuates between positive and negative may be applied to each of the upper electrode layer 44 and the lower electrode layer 45 while N₂ gas is being introduced into the reaction chamber 17. As a result, deposit and so on attached to the deposit shield 43 can be removed efficiently through electromagnetic stress. Moreover, removed particles are efficiently exhausted out of the chamber 11 by viscous flow produced by the N₂ gas.

Furthermore, in the substrate processing apparatus 10, the upper electrode layer 44 and the lower electrode layer 45 are formed by thermally spraying a conductive material such as tungsten. An electrode layer of a desired shaped can thus easily be realized, and hence a desired potential distribution can easily be realized over the surface of the deposit shield 43. As a result, ideal plasma distribution control and particle behavior in the processing space S can be realized.

In the substrate processing apparatus 10 described above, the electrode layers of the deposit shield 43 are the upper electrode layer 44 and the lower electrode layer 45. However, the number of electrode layers of the deposit shield 43 is not limited thereto, but rather may instead be 1, or 3 or more.

Next, a substrate processing apparatus according to a second embodiment of the present invention will be described.

The present embodiment is basically the same as the first embodiment described above in terms of construction and operation, only the form of the deposit shield differing to in the first embodiment. Features of the construction and operation that are the same as in the first embodiment will thus not be described, only features of the construction and operation that are different to in the first embodiment being described below.

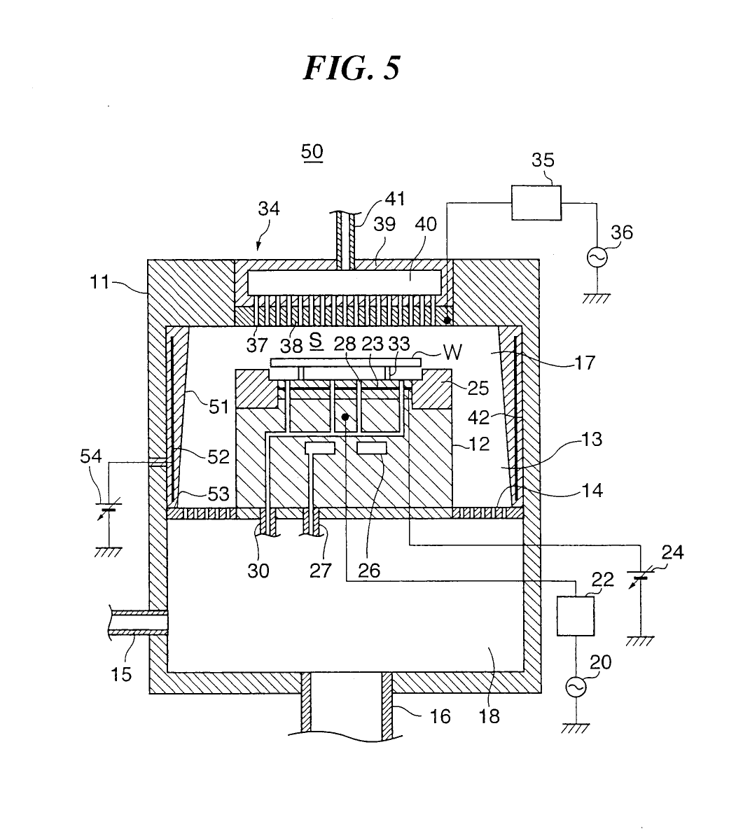

FIG. 5 is a sectional view schematically showing the construction of the substrate processing apparatus according to the present embodiment.

As shown in FIG. 5, in the substrate processing apparatus 50, a deposit shield 51 is disposed on the side wall 42 of the chamber 11 as a side wall component that covers the side wall 42 and faces onto the processing space S. The deposit shield 51 has an electrode layer 52, and an insulating portion 53 formed such as to enclose the electrode layer 52.

The deposit shield 51 is a cylindrical component, and is disposed such as to surround the susceptor 12. Moreover, the electrode layer 52 is also cylindrical, and is disposed such as to surround the susceptor 12. The electrode layer 52 thus does not face the front surface of a wafer W mounted on the susceptor 12.

Moreover, in the deposit shield 51, the insulating portion 53 is present between the electrode layer 52 and the processing space S. The electrode layer 52 is thus not exposed to the reaction chamber 17. A DC power source 54 is electrically connected to the electrode layer 52.

The deposit shield 51 is manufactured by thermally spraying yttria onto the side wall 42 of the chamber 11 so as form an insulating foundation layer, thermally spraying a conductive material that adheres well to ceramics, for example tungsten nichrome or niobium onto the foundation layer so as to form the electrode layer 52, and then thermally spraying yttria onto the electrode layer 52 so as to form a coating film. Here, the yttria foundation layer and coating film constitute the insulating portion 53.

For the deposit shield 51, the thickness of the insulating portion 53 present between the electrode layer 52 and the processing space S is not constant, but rather decreases from in the vicinity of the processing space S toward in the vicinity of the manifold 18 (from the top downward in FIG. 5). Here, a potential produced at the surface of the deposit shield 51 (hereinafter referred to as the “surface potential”) when a DC voltage is applied to the electrode layer 52 varies in accordance with the thickness of the insulating portion 53. Specifically, the lower the thickness of the insulating portion 53, the greater the absolute value of the surface potential, and hence for the deposit shield 51, the absolute value of the surface potential increases from in the vicinity of the processing space S toward in the vicinity of the manifold 18. The Coulomb force due to the surface potential is thus greater in the vicinity of the manifold 18 than in the vicinity of the processing space S. As a result, charged particles move through the side exhaust path 13 while being accelerated from in the vicinity of the processing space S toward in the vicinity of the manifold 18. Viscous flow arises in the side exhaust path 13 from the reaction chamber 17 toward the manifold 18, and hence particles P that have moved into the vicinity of the manifold 18 are led through the holes in the baffle plate 14 and into the manifold 18. Having been led into the manifold 18, the particles P are exhausted out of the chamber 11 by the roughing exhaust pipe 15 and the main exhaust pipe 16.

According to the substrate processing apparatus 50 described above, in the deposit shield 51, the thickness of the insulating portion 53 present between the electrode layer 52 and the processing space S decreases from in the vicinity of the processing space S toward in the vicinity of the manifold 18. As the thickness of the insulating portion 53 decreases, the absolute value of the surface potential increases, and hence over the surface of the deposit shield 51, the absolute value of the surface potential increases from in the vicinity of the processing space S toward in the vicinity of the manifold 18. Charged particles are thus led while being accelerated into the manifold 18. As a result, particles can be removed from the reaction chamber 17 effectively.

Moreover, the substrate processing apparatus according to each of the embodiments described above is an etching apparatus; however, the substrate processing apparatus to which the present invention is applied is not limited to being an etching apparatus, but rather may be any substrate processing apparatus that uses plasma, for example a CVD apparatus or an ashing apparatus.

Moreover, the substrates subjected to the etching processing in the substrate processing apparatus according to each of the embodiments described above are not limited to being semiconductor wafers, but rather may instead be any of various substrates used in LCDs (Liquid Crystal Displays), FPDs (Flat Panel Displays) or the like, photomasks, CD substrates, printed substrates, or the like.

The above-described embodiments are merely exemplary of the present invention, and are not to be construed to limit the scope of the present invention.

The scope of the present invention is defined by the scope of the appended claims, and is not limited to only the specific descriptions in this specification. Furthermore, all modifications and changes belonging to equivalents of the claims are considered to fall within the scope of the present invention.

What is claimed is:

1. A substrate processing apparatus comprising:
a processing chamber that houses a substrate and carries out predetermined plasma processing on the substrate;
a susceptor that is disposed in the processing chamber and mounts the substrate thereon so as to function as a lower electrode;
a shower head that is disposed in a ceiling portion of the processing chamber and functions as an upper electrode;
an insulating portion that is disposed such as to cover a side wall of the processing chamber;
an upper electrode layer and a lower electrode layer that are disposed in the insulating portion; and
an exhaust portion that exhausts gas from the processing chamber, wherein
respective DC voltages applied to the upper electrode layer and the lower electrode layer are controlled individually, and
a thickness of the insulating portion decreases from a processing space in the processing chamber toward the exhaust portion.

2. A substrate processing apparatus as claimed in claim 1, wherein the absolute value of the DC voltage applied to the lower electrode layer is not less than the absolute value of the DC voltage applied to the upper electrode layer.

3. A substrate processing apparatus as claimed in claim 1, wherein each of the upper electrode layer and the lower electrode layer has at least a first terminal and a second terminal, and a predetermined difference is set between a voltage applied to the first terminal and a voltage applied to the second terminal.

4. A substrate processing apparatus as claimed in claim 1, wherein the insulating portion is formed by spraying of yttria.

5. A substrate processing apparatus as claimed in claim 1, wherein the upper electrode layer and the lower electrode layer are formed by spraying of conductive material.

6. A substrate processing apparatus as claimed in claim 1, wherein the upper electrode layer and the lower electrode layer function as heaters.
